(19) United States
(12) Patent Application Publication
(10) Pub. No.: US 2022/0375845 A1
(43) Pub. Date: Nov. 24, 2022

(54) SEMICONDUCTOR DEVICE

(71) Applicant: FUJI ELECTRIC CO., LTD., Kawasaki-shi (JP)

(72) Inventors: Norihiro DAICHO, Matsumoto-city (JP); Fumihiko MOMOSE, Higashi-chikuma-gun (JP)

(73) Assignee: FUJI ELECTRIC CO., LTD., Kawasaki-shi (JP)

(21) Appl. No.: 17/723,109

(22) Filed: Apr. 18, 2022

(30) Foreign Application Priority Data
May 24, 2021 (JP) 2021-087136

(51) Int. Cl. H01L 23/50; H01L 23/10; H01L 23/528; H01L 23/498

(52) U.S. Cl. CPC H01L 23/50; H01L 23/10; H01L 23/5286; H01L 23/49811; H01L 25/072

(57) ABSTRACT

A semiconductor device, including a sealing body portion, a nut and a bus bar. The sealing body portion has a housing portion formed on a front surface thereof, the sealing body portion including a semiconductor chip contained therein and a plurality of pin-shaped external connection terminals electrically connected to the semiconductor chip. The nut has a screw hole and disposed in the housing portion. The bus bar is arranged opposite the housing portion, and includes a fastening area with an opening portion opposite the screw hole of the nut, and a bonding area that is outside the fastening area and is connected to the plurality of external connection terminals. The sealing body portion has a protrusion adjacent to the bonding area of the bus bar.

### CROSS-REFERENCE TO RELATED APPLICATION

This application is based upon and claims the benefit of priority of the prior Japanese Patent Application No. 2021-087136, filed on May 24, 2021, the entire contents of which are incorporated herein by reference.

### BACKGROUND OF THE INVENTION

### 1. Field of the Invention

The embodiments discussed herein relate to a semiconductor device.

### 2. Background of the Related Art

With semiconductor devices, power devices and a plurality of external connection terminals electrically connected thereto are sealed with resin. The power devices are insulated gate bipolar transistors (IGBTs), power metal oxide semiconductor field effect transistors (MOSFETs), or the like. The plurality of external connection terminals extend vertically from the front surface of a semiconductor device and bus bars are fixed to the plurality of external connection terminals (see, for example, Japanese Laid-open Patent Publication No. 2017-112250).

For example, a bus bar is fixed in the following way. A main terminal which extends vertically from the front surface of the semiconductor device, which has the shape of a flat plate, and in which a penetration hole is made is bent to the side of the front surface and a bus bar is fastened to the penetration hole with a bolt (see, for example, Japanese Patent No. 6516024).

Furthermore, the following method is proposed as an example of a method for fastening with a bolt. In order to prevent a bolt from rotating at the time of fastening with the bolt, a terminal nut cover is used. The terminal nut cover has a concave portion which may cover and support a terminal nut (see, for example, Japanese Laid-open Patent Publication No. H09-69603).

With the above semiconductor device, when a bus bar having a penetration hole made in the central portion is bonded to an external connection terminal and a connection terminal of an external device (second bus bar) is fastened to the bus bar with a bolt, the bus bar may rotate with the rotation of the bolt. However, the bus bar is bonded to the external connection terminal. As a result, a portion of the external connection terminal at which the bus bar is bonded may bend and deform with the rotation of the bus bar. Furthermore, if damage, such as a crack, occurs to a portion of resin which supports the external connection terminal with the deformation of the external connection terminal, then insulation may deteriorate. This leads to deterioration in the reliability of the semiconductor device.

### SUMMARY OF THE INVENTION

According to an aspect, there is provided a semiconductor device including a sealing body portion having a housing portion formed on a front surface thereof, the sealing body portion including a semiconductor chip contained therein and a plurality of pin-shaped external connection terminals electrically connected to the semiconductor chip; a nut having a screw hole and disposed in the housing portion; and a bus bar arranged opposite the housing portion, and including a fastening area with an opening portion opposite the screw hole of the nut, and a bonding area that is outside the fastening area and is connected to the plurality of external connection terminals, wherein the sealing body portion has a protrusion adjacent to the bonding area of the bus bar.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a side view of the semiconductor device according to the first embodiment;

FIG. 3 is a sectional view of the semiconductor device according to the first embodiment;

FIG. 4 is a plan view illustrating a main part of the semiconductor device according to the first embodiment to which a bus bar is fixed;

FIG. 5 is a sectional view of the semiconductor device according to the first embodiment to which the bus bar is fixed;

FIG. 6 is a plan view illustrating a main part of the semiconductor device according to modification 1-1 of the first embodiment to which a bus bar is fixed;

FIG. 7 is a plan view illustrating a main part of the semiconductor device according to modification 1-2 of the first embodiment to which a bus bar is fixed;

FIG. 8 is a plan view illustrating a main part of the semiconductor device according to modification 1-3 of the first embodiment to which a bus bar is fixed;

FIG. 9 is a plan view illustrating a main part of the semiconductor device according to modification 1-4 of the first embodiment to which a bus bar is fixed;

FIG. 10 is a plan view illustrating a main part of the semiconductor device according to modification 1-5 of the first embodiment to which a bus bar is fixed;

FIG. 11 is a plan view illustrating a main part of the semiconductor device according to modification 1-6 of the first embodiment to which a bus bar is fixed;

FIG. 12 is a sectional view of the semiconductor device according to the first embodiment to which another bus bar is fixed;

FIG. 13 is a sectional view of a semiconductor device according to a second embodiment to which a bus bar is fixed; and

FIG. 14 is a plan view illustrating a main part of the semiconductor device according to the second embodiment to which the bus bar is fixed.

### DETAILED DESCRIPTION OF THE INVENTION

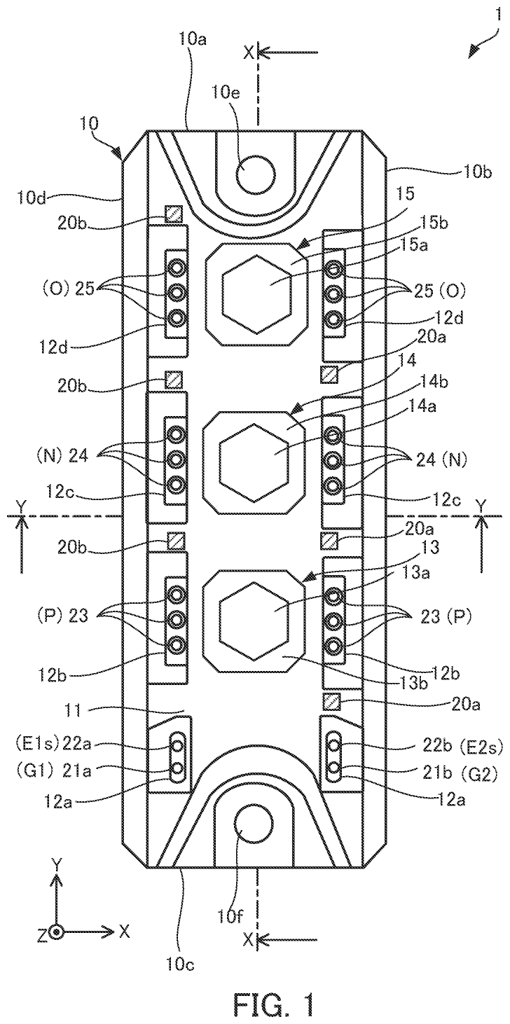

Embodiments will now be described by reference to the accompanying drawings. In the following description, a “front surface” or an “upper surface” indicates an X-Y plane of a semiconductor device 1 of FIG. 1 which faces the upper side (+Z direction). Similarly, an “upside” indicates the upward direction (+Z direction) of the semiconductor device 1 of FIG. 1. A “back surface” or a “lower surface” indicates the X-Y plane of the semiconductor device 1 of FIG. 1 which faces the lower side (−Z direction). Similarly, a “downside” indicates the downward direction (−Z direction) of the semiconductor device 1 of FIG. 1. These terms mean the same directions as needed in the other drawings. The “front surface,” the “upper surface,” the “upside,” the “back surface,” the “lower surface,” the “downside,” and a “side” are simply used as expedient representation for specifying relative positional relationships and do not limit the technical idea of the present disclosure. For example, the “upside” or the “downside” does not always mean the vertical direction relative to the ground. That is to say, a direction indicated by the “upside” or the “downside” is not limited to the gravity direction. Furthermore, in the following description a “main ingredient” indicates an ingredient contained at a rate of 80 volume percent (vol %) or more.

### First Embodiment

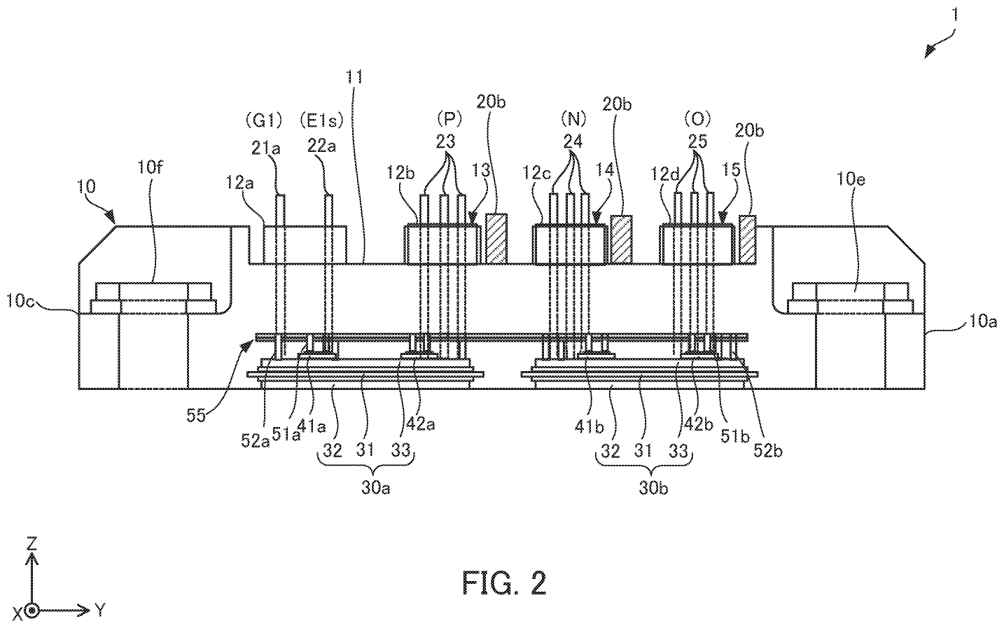

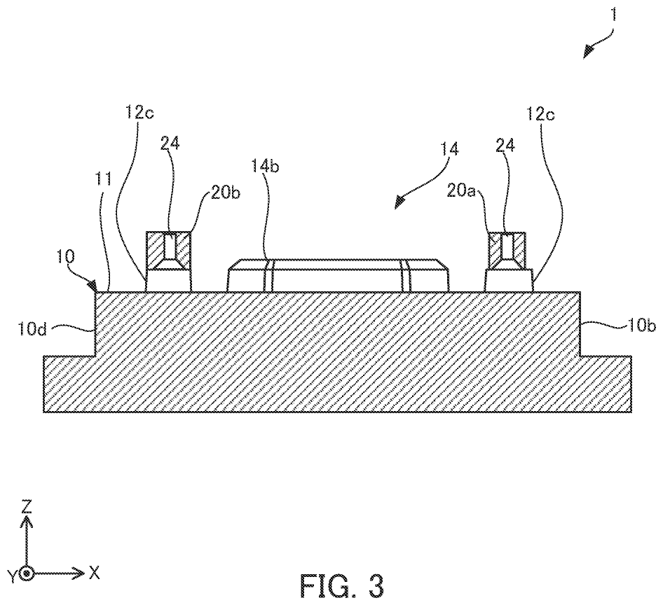

An example of a semiconductor device used in a first embodiment will be described with reference to FIGS. through 3. FIG. 1 is a plan view of a semiconductor device according to a first embodiment. FIG. 2 is a side view of the semiconductor device according to the first embodiment. FIG. 3 is a sectional view of the semiconductor device according to the first embodiment. FIG. 2 is a sectional view taken along the dot-dash line X-X of FIG. 1. The dot-dash line X-X is a center line in the longitudinal direction of a semiconductor device 1 which passes through the center of the semiconductor device 1. FIG. 3 is a sectional view taken along the dot-dash line Y-Y of FIG. 1. However, the inside of the semiconductor device 1 is not illustrated in FIG. 3.

The semiconductor device 1 has a cuboid sealing body portion 10. External connection terminals 21a, 21b, 22a, 22b, and 23 through 25 extend upward (in the +Z direction) from a front surface 11 of the sealing body portion 10 perpendicularly to the front surface 11.

An approximately rectangular front surface 11 of the sealing body portion 10 is enclosed in a plan view of the semiconductor device by side walls 10a through 10d on all sides. Furthermore, the side walls 10a and 10c correspond to the lateral direction of the sealing body portion 10 and the side walls 10b and 10d correspond to the longitudinal direction of the sealing body portion 10. Connection portions at the four corners of the side walls 10a through 10d are not always at a right angle. Each of the connection portions at the four corners of the side walls 10a through 10d may have an R-shape or be chamfered. Connection portions of the front surface 11 and the side walls 10a through 10d are not always at a right angle. Each of the connection portions of the front surface 11 and the side walls 10a through 10d may have an R-shape or be chamfered.

Fastening holes 10e and 10f are made along the dot-dash line X-X (center line) in the front surface 11.

Nut housing stands 13 through 15 are formed along the dot-dash line X-X (center line) on the front surface 11. The fastening holes 10e and 10f are made on the sides of the side walls 10a and 10c, respectively, so as to pierce the sealing body portion 10. The semiconductor device 1 is fixed to a determined area by inserting screws into the fastening holes 10e and 10f.

The nut housing stands 13 through 15 are cuboid. The nut housing stands 13 through 15 and the front surface 11 are integrally formed. For example, opposite surfaces 13b through 15b, which are the front surfaces of the nut housing stands 13 through 15 respectively, are octagonal in a plan view. However, the opposite surfaces 13b through 15b may be polygonal or circular. That is to say, the opposite surfaces 13b through 15b need only have areas in which housing portions 13a through 15a, respectively, described later may be formed. If the opposite surfaces 13b through 15b are polygonal in the plan view, then each corner portion may have an R-shape or be chamfered. Furthermore, the opposite surfaces 13b through 15b are situated above the front surface 11 (in the +Z direction). The housing portions 13a through 15a are formed in the opposite surfaces 13b through 15b of the nut housing stands through 15 respectively. The housing portions 13a through 15a are areas opened outward (in the +Z direction) and nuts are completely housed in the housing portions 13a through 15a. The housing portions 13a through 15a do not pierce the nut housing stands 13 through 15 respectively and are concave. The shape of the housing portions 13a through 15a corresponds in the plan view to that of bolts. In the case of FIG. 1, the shape of the housing portions 13a through 15a is hexagonal in the plan view.

Furthermore, in total six external connection terminals 23, six external connection terminals 24, and six external connection terminals 25 extend upward perpendicularly to the front surface 11 in the plan view. The six external connection terminals 23, the six external connection terminals 24, and the six external connection terminals 25 are arranged with the nut housing stands 13 through 15, respectively, therebetween so as to be line-symmetric with respect to the dot-dash line X-X. In addition, the external connection terminals 23 through 25 extend from the front surfaces of terminal blocks 12b through 12d, respectively, integrally formed with the front surface 11. The terminal blocks 12b through 12d are formed with the nut housing stands 13 through 15, respectively, therebetween and are cuboid. Specifically, the terminal blocks 12b through 12d are arranged along the side walls 10b and 10d in the plan view and have a cuboid shape. The length of long sides of each cuboid is approximately equal in the plan view to the length in the Y direction of the nut housing stand 13, 14, or 15. For example, in total the six external connection terminals 24 extend from the terminal blocks 12c on both sides of the nut housing stand (on the sides of the side walls 10b and 10d).

Furthermore, the external connection terminals 21a, 21b, 22a, and 22b extend upward perpendicularly to the front surface 11 on the side of the side wall 10c. In addition, the external connection terminals 21a and 22a extend from the front surface of a terminal block 12a integrally formed with the front surface 11 on the side of the side wall 10d. The external connection terminals 21b and 22b extend from the front surface of a terminal block 12a integrally formed with the front surface 11 on the side of the side wall 10b.

With the sealing body portion 10, the nut housing stands 13 through 15 and the terminal blocks 12a through 12d and the front surface 11 are integrally formed in this way. The sealing body portion 10 is formed by performing sealing with resin in a determined metal mold including semiconductor chips and the like described later. Such resin contains a thermoplastic resin as a main ingredient. A thermoplastic resin is polyphenylene sulfide resin, polybutylene terephthalate resin, polybutylene succinate resin, polyamide resin, acrylonitrile butadiene styrene resin, or the like.

Furthermore, protrusions 20a and 20b and the front surface 11 are integrally formed for the nut housing stands 13 through 15. For example, a protrusion 20b is formed on the sides of the side walls 10d and 10a on the front surface 11 and a protrusion 20a is formed on the sides of the side walls 10b and 10c on the front surface 11, for the nut housing stand 14. That is to say, the protrusions 20a and 20b are point-symmetric with respect to the housing portion 14a of the nut housing stand 14. In FIGS. 1 through 3, the protrusions 20a and 20b are hatched. However, the protrusions 20a and 20b may be made of the same material that is used for forming the sealing body portion 10. The details of the protrusions 20a and 20b will be described later.

With the semiconductor device 1, insulated circuit boards 30a and 30b, first semiconductor chips 41a and 41b, second semiconductor chips 42a and 42b, and a printed-circuit board 55 are sealed by the sealing body portion 10. Each of the insulated circuit boards 30a and 30b includes an insulating board 31, a metal plate 32 formed on the back surface of the insulating board 31, and a circuit board 33 formed over the front surface of the insulating board 31. The insulating board 31 and the metal plate 32 are rectangular in the plan view. Furthermore, corner portions of the insulating board 31 and the metal plate 32 may be R-chamfered or C-chamfered. The metal plate 32 is smaller in size than the insulating board 31 in the plan view and is formed inside the insulating board 31. The insulating board 31 has an insulating property and is made of a material having high thermal conductivity. The insulating board 31 is made of a ceramic or an insulating resin. Such a ceramic is aluminum oxide, aluminum nitride, silicon nitride, or the like. Such an insulating resin is a paper phenolic board, a paper epoxy board, a glass composite board, a glass epoxy board, or the like. The insulating board 31 has a thickness in the range of 0.2 mm to 2.0 mm inclusive.

The metal plate 32 is smaller in area than the insulating board 31 and is larger than an area in which the circuit board 33 is formed. The metal plate 32 is rectangular. This is the same with the insulating board 31. Furthermore, corner portions of the metal plate 32 may be R-chamfered or C-chamfered. The metal plate 32 is smaller in size than the insulating board 31 and is formed on the entire surface except edge portions of the insulating board 31. The metal plate 32 contains as a main ingredient metal, such as copper, aluminum, or an alloy containing at least one of them, having high thermal conductivity. In addition, the metal plate 32 has a thickness in the range of 0.1 mm to 2.5 mm inclusive. In order to improve the corrosion resistance of the metal plate 32, plating treatment may be performed. At this time, nickel, a nickel-phosphorus alloy, a nickel-boron alloy, or the like is used as a plating material.

The circuit board 33 is made of metal, such as copper, aluminum, or an alloy containing as a main ingredient at least one of them, having good electrical conductivity. Furthermore, the circuit board 33 has a thickness in the range of 0.1 mm to 2.0 mm inclusive. In order to improve corrosion resistance, plating treatment may be performed on the surface of the circuit board 33. At this time, nickel, a nickel-phosphorus alloy, a nickel-boron alloy or the like is used as a plating material. The circuit board 33 illustrated in FIG. 2 is an example. The number, shape, size, or the like of the circuit boards 33 may be properly selected as needed.

Direct copper bonding (DCB) substrates, active metal brazed (AMB) substrates, resin insulating substrates, or the like may be used as the insulated circuit boards 30a and 30b each having the above structure.

With the semiconductor device 1, the back surfaces of the metal plates 32 of the insulated circuit boards 30a and 30b are exposed. A cooling unit may be fixed to the back surface of the semiconductor device 1 with a bonding member therebetween. A bonding member used at this time is solder, a brazing filler metal, or a sintered metal body. Pb-free solder is used as the solder. Pb-free solder contains as a main ingredient an alloy containing at least two of tin, silver, copper, zinc, antimony, indium, bismuth, and the like. Furthermore, the solder may contain an additive such as nickel, germanium, cobalt, or silicon. The solder containing an additive improves wettability, a gloss, and bonding strength and reliability is improved. The brazing filler metal contains as a main ingredient at least one of an aluminum alloy, a titanium alloy, a magnesium alloy, a zirconium alloy, a silicon alloy, and the like. The cooling unit is bonded to the insulated circuit boards 30a and 30b by brazing by the use of such a bonding member. For example, the sintered metal body contains silver and a silver alloy as a main ingredient. Alternatively, a bonding member may be a thermal interface material. For example, the thermal interface material is an elastomer sheet, room temperature vulcanization (RTV) rubber, gel, or an adhesive containing a phase change material or the like. By fixing the cooling unit to the back surface of the semiconductor device 1 with such a brazing filler metal or a thermal interface material therebetween, the heat dissipation property of the semiconductor device 1 is improved. The cooling unit is a heat sink including a plurality of fins, a water-cooling cooler, or the like. The heat sink is made of aluminum, iron, silver, copper, or an alloy containing at least one of them which has high thermal conductivity. In addition, in order to improve corrosion resistance, a material such as nickel may be formed on the surface of the heat sink by plating treatment or the like. Specifically, a nickel-phosphorus alloy, a nickel-boron alloy, or the like may be used in place of nickel.

Each of the first semiconductor chips 41a and 41b and the second semiconductor chips 42a and 42b includes a power device element made of silicon or silicon carbide. Furthermore, for example, each of the first semiconductor chips 41a and 41b and the second semiconductor chips 42a and 42b has a thickness in the range of 40 μm to 250 μm inclusive. The power device element is a switching element or a diode element.

Each of the first semiconductor chips 41a and 41b includes a switching element such as an IGBT or a power MOSFET. For example, each of the first semiconductor chips 41a and 41b has a drain electrode (or a collector electrode) as a main electrode on the back surface and has a gate electrode as a control electrode and a source electrode (or an emitter electrode) as a main electrode on the front surface.

Each of the second semiconductor chips 42a and 42b includes a diode element. The diode element is a free wheeling diode (FWD) such as a Schottky barrier diode (SBD) or a P-intrinsic-N (PiN) diode. Each of the second semiconductor chips 42a and 42b has a cathode electrode as a main electrode on the back surface and has an anode electrode as a main electrode on the front surface.

At least one of the switching elements of the first semiconductor chips 41a and 41b and at least one of the diode elements of the second semiconductor chips 42a and 42b are selected as needed and their back surfaces are bonded mechanically and electrically to the determined circuit boards 33 with a bonding member. A bonding member used at this time is solder or a sintered metal body. Pb-free solder is used as the solder. Pb-free solder contains as a main ingredient an alloy containing at least two of tin, silver, copper, zinc, antimony, indium, bismuth, and the like. Furthermore, the solder may contain an additive such as nickel, germanium, cobalt, or silicon. The solder containing an additive improves wettability, a gloss, and bonding strength and reliability is improved. For example, metals used for the sintered metal body are silver and a silver alloy.

Furthermore, a reverse-conducting (RC)-IGBT having the functions of an IGBT and an FWD may be used in place of the first semiconductor chip 41a the second semiconductor chip 42a or the first semiconductor chip 41b and the second semiconductor chip 42b.

The printed-circuit board 55 includes an insulating layer and a metal layer which is formed on at least one of the front surface and back surface of the insulating layer and which is a wiring pattern. The insulating layer includes a substrate and resin with which the substrate is impregnated. The substrate is paper, glass cloth, something containing paper or glass cloth, or the like. The resin is phenolic resin, epoxy resin, polyimide resin, or the like. A paper phenolic board, a paper epoxy board, a glass epoxy board, a composite substrate epoxy board, or a glass polyimide board is taken as a concrete example. The metal layer is made of metal, such as copper, aluminum, or an alloy containing at least one of them as a main ingredient, having good electrical conductivity. The above printed-circuit board 55 is arranged opposite the front surfaces of the insulated circuit boards 30a and 30b at a determined distance therefrom.

Furthermore, conductive posts 51a and 51b electrically connect the printed-circuit board 55 and the first semiconductor chips 41a and 41b and the second semiconductor chips 42a and 42b respectively. Conductive posts 52a and 52b electrically connect the printed-circuit board 55 and the insulated circuit boards 30a and 30b respectively. The conductive posts 51a, 51b, 52a, and 52b have the shape of a cylinder or a prism. The conductive posts 51a, 51b, 52a, and 52b are made of a material, such as silver, copper, nickel, or an alloy containing at least one of them, having good electrical conductivity.

Furthermore, the external connection terminals 21a, 21b, 22a, 22b, and 23 through 25 have the shape of a cylinder or a prism. The external connection terminals 21a, 21b, 22a, 22b, and 23 through 25 have the shape of what is called a pin. Lower end portions of the external connection terminals 21a, 21b, 22a, 22b, and 23 through 25 are bonded electrically and mechanically to the insulated circuit boards 30a and 30b. As stated above, upper end portions of the external connection terminals 21a, 21b, 22a, 22b, and 23 through 25 extend upward perpendicularly to the front surface 11 of the sealing body portion 10. The external connection terminals 21a, 21b, 22a, 22b, and 23 through 25 are connected in the following way. The external connection terminals 21a, 21b, 22a, and 22b are control terminals for controlling switching of the semiconductor device 1. The external connection terminals 21a and 21b are control terminals (G1 and G2 terminals) electrically connected to the control electrodes of the first semiconductor chips 41a and 41b respectively. The external connection terminals 22a and 22b are current sense terminals (E1s and E2s terminals) electrically connected to the emitter electrodes of the first semiconductor chips 41a and 41b respectively. In addition, the external connection terminals 23, 24, and 25 are main terminals through which a main current is inputted or outputted. The external connection terminal 23 is electrically connected to the collector electrode of the first semiconductor chip 41a and is an input terminal (P terminal) through which a plus-side input current flows. The external connection terminal 24 is electrically connected to the emitter electrode of the first semiconductor chip 41b described later and is an input terminal (N terminal) through which a minus-side input current flows. The external connection terminal 25 is electrically connected to the emitter electrode of the first semiconductor chip 41a and the collector electrode of the first semiconductor chip 41b and is an output terminal (O terminal) through which an output current flows. The external connection terminals 21a, 21b, 22a, 22b, and 23 through 25 are also made of a material, such as silver, copper, nickel, or an alloy containing at least one of them, having good electrical conductivity.

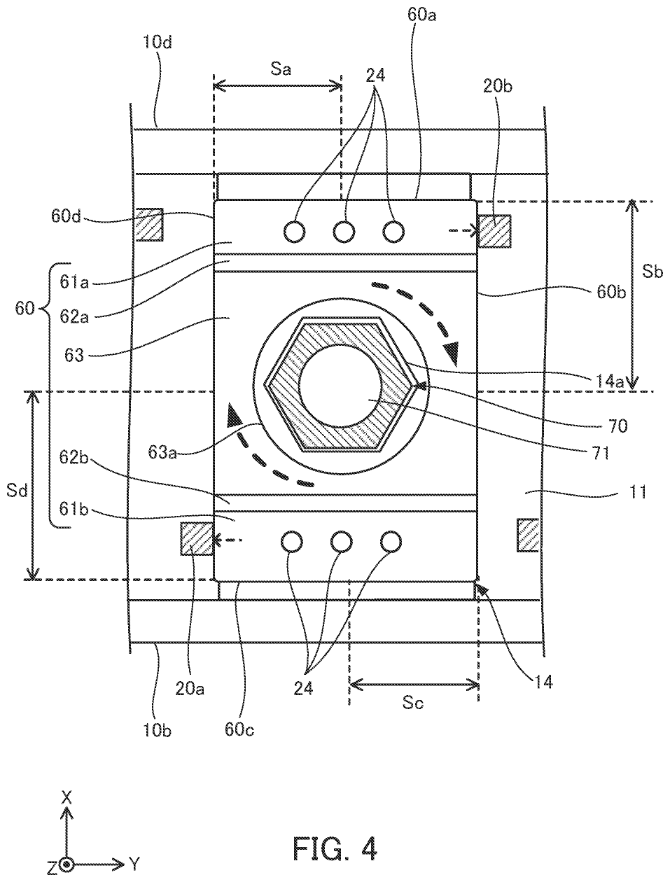

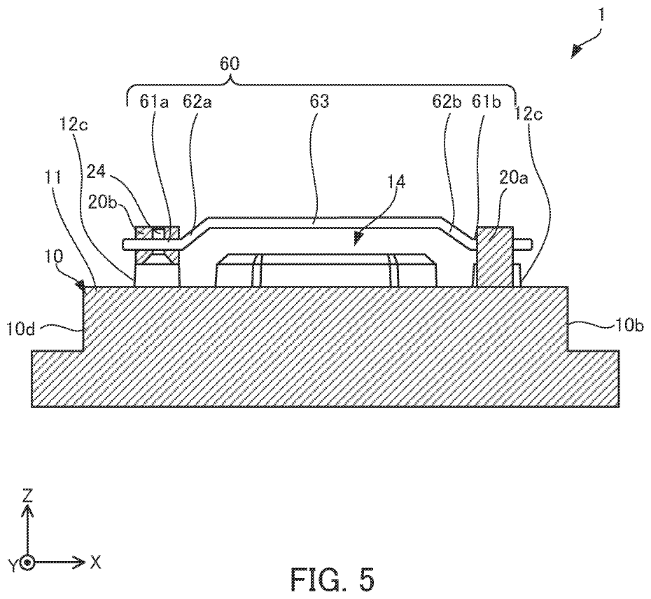

The semiconductor device 1 to which bus bars are fixed according to the nut housing stands 13 through 15 will now be described with reference to FIGS. 4 and 5. A case where a bus bar is fixed over the nut housing stand 14 will be described. A bus bar is fixed over each of the nut housing stands 13 and 15 in the same way.

FIG. 4 is a plan view illustrating a main part of the semiconductor device according to the first embodiment to which a bus bar is fixed. FIG. 5 is a sectional view of the semiconductor device according to the first embodiment to which the bus bar is fixed. FIG. 4 is an enlarged plan view of the vicinities of a bus bar 60 fixed to the semiconductor device 1 over the nut housing stand 14. Furthermore, FIG. 5 is a sectional view taken along the dot-dash line Y-Y of FIG. 1 at the time of the bus bar 60 being fixed. FIG. 4 illustrates a case where a nut 70 which has a screw hole 71 made in a central portion and which is hexagonal in the plan view is housed in the housing portion 14a.

The bus bar 60 is arranged opposite the nut housing stand 14. The bus bar 60 includes bonding areas 61a and 61b, connection areas 62a and 62b, and a fastening area 63. Each of these areas is rectangular in the plan view and the bus bar 60 as a whole is also rectangular. The bus bar 60 is surrounded on all sides by short sides 60a and 60c and long sides 60b and 60d in the plan view. Therefore, the bus bar 60 is arranged over the nut housing stand 14 so that the short sides 60a and 60c will be parallel to the side walls 10d and 10b of the sealing body portion 10 and so that the long sides 60b and 60d will be parallel to the side walls 10a and 10c.

The bonding areas 61a and 61b are set on both end portions of the bus bar 60. The upper end portions of the external connection terminals 24 protrude from the bonding areas 61a and 61b and the bonding areas 61a and 61b are bonded to the external connection terminals 24 with solder. The fastening area 63 is arranged opposite the nut housing stand 14 and protrudes vertically upward (in the +Z direction) from the bonding areas 61a and 61b. The fastening area 63 is situated above (in the +Z direction of) the upper end portions of the external connection terminals 24 extending from the bonding areas 61a and 61b. Furthermore, with the fastening area 63, an opening portion 63a opposite the housing portion 14a of the nut housing stand 14 is opened in the plan view. As illustrated in FIG. 4, for example, the opening portion 63a has area which makes it possible for the opening portion 63a to surround the housing portion 14a of the nut housing stand 14 in the plan view. In addition, at this time the opening portion 63a is opposed to the nut 70. The connection areas 62a and 62b integrally connect end portions of the bonding areas 61a and 61b opposite the connection areas 62a and 62b and end portions of the fastening area 63 on the sides of the side walls 10d and 10b respectively.

The bus bar 60 contains as a main ingredient metal, such as copper, aluminum, or an alloy containing at least one of them, having good electrical conductivity. Moreover, in order to improve the corrosion resistance of the bus bar 60, plating treatment may be performed. A plating material used at this time is nickel, a nickel-phosphorus alloy, a nickel-boron alloy, or the like. For example, the bus bar 60 is formed in the following way. A member having the shape of a flat plate is formed from a flat plate by punching and press working is performed. By doing so, the bonding areas 61a and 61b, the connection areas 62a and 62b, and the fastening area 63 are formed.

Furthermore, the protrusions 20b and 20a are formed on the front surface 11 so as to come in contact with the long sides 60a and 60b, respectively, of the bus bar 60. In particular, the protrusions 20b and 20a are formed so as to be point-symmetric with respect to the opening portion 63a. In addition, the protrusions 20b and 20a are in contact with contact areas Sb and Sd of the long sides 60b and 60d respectively. There is no need for the protrusions 20b and 20a to be in contact with the bus bar 60. The protrusions 20b and 20a may be formed so that there will be small gaps between the protrusions 20b and 20a and the bus bar 60. Moreover, there is need for the height of the protrusions 20b and 20a to be greater in side view than the height of the front surface of the bus bar 60 from the front surface 11. With the semiconductor device 1 according to the first embodiment, the upper end portions of the protrusions 20b and 20a are situated over at least the bonding areas 61a and 61b of the bus bar 60 bonded to the external connection terminals 24. Furthermore, the protrusions 20b and 20a has the shape of a pillar and are square in the plan view. However, the protrusions 20b and 20a are simply taken as an example. The protrusions 20b and 20a has the shape of a pillar and may be polygonal, circular, or elliptical in the plan view. In addition, as described later, the size of the protrusions 20b and 20a need only maintain strength which suppresses rotation of the bus bar 60.

A second bus bar (connection terminal) is fixed from the outside to the bus bar 60 fixed in this way to the semiconductor device 1 over the nut housing stand 14. Furthermore, a bolt (not illustrated) pierces the connection terminal and the opening portion 63a of the bus bar 60 and is fastened to the nut 70 in the housing portion 14a. At this time the bolt fastened is rotated in a clockwise direction indicated by a dashed arrow in FIG. 4 and is fastened to the nut 70 in the housing portion 14a.

A case where the protrusions 20b and 20a are not formed will now be described. If a bolt is rotated in a clockwise direction and is fastened, then the bus bar 60 may also rotate in the clockwise direction with the rotation of the bolt. In this case, force is applied from the bus bar 60 which rotates to the external connection terminals 24 bonded to the bus bar 60. As a result, the external connection terminals 24 may deform. Alternatively, stress is also applied to the terminal blocks 12c which support the external connection terminals 24 which deform. Accordingly, cracks appear and the terminal blocks 12c break. As a result, insulation is not maintained.

With the semiconductor device 1, on the other hand, the bus bar 60 is arranged opposite the nut housing stand 14 over the front surface 11 of the sealing body portion 10 and is bonded to the external connection terminals 24. The protrusions 20b and 20a are formed so as to be in contact with the sides of the short sides 60a and 60c of the long sides 60b and 60d, respectively, of the bus bar 60. Therefore, even when a bolt is rotated in the clockwise direction to make an attempt to rotate the bus bar 60 in the clockwise direction, rotation of the bus bar 60 is suppressed by the protrusions 20b and 20a. As a result, force is not applied from the bus bar 60 to the external connection terminals 24. This prevents the external connection terminals 24 from deforming. Furthermore, stress applied to the terminal blocks 12c which support the external connection terminals 24 is suppressed and the sealing body portion 10 does not break. Accordingly, insulation is maintained.

Furthermore, when the bus bar 60 is fixed, the protrusions 20b and 20a are also used for registration. As a result, registration between the bus bar 60 and the external connection terminals 24 is easily performed and the bus bar 60 is easily bonded to the external connection terminals 24.

The above semiconductor device includes the sealing body portion 10. The sealing body portion 10 has the front surface 11, the housing portions 13a through 15a opened outward with respect to the front surface 11, the first semiconductor chips 41a and 41b and the second semiconductor chips 42a and 42b, and the external connection terminals 23 through 25 electrically connected to the first semiconductor chips 41a and 41b and the second semiconductor chips 42a and 42b. Furthermore, the above semiconductor device includes the nuts 70 each having the screw hole 71 and housed in the housing portions 13a through 15a. Moreover, the above semiconductor device includes the bus bars 60 arranged opposite the housing portions 13a through 15a, having the fastening areas 63 each having the opening portion 63a opposite the screw hole 71 of the nut 70, and having the bonding areas 61a and 61b on portions outside the fastening areas 63 connected to the external connection terminals 23 through 25. Furthermore, the sealing body portion 10 has the protrusions 20a and 20b adjacent to side walls of the bus bars 60. As a result, even when a bolt is rotated in the clockwise direction with respect to the nut 70 to make an attempt to rotate the bus bar 60 in the clockwise direction, rotation of the bus bar 60 is suppressed by the protrusions 20b and 20a. As a result, force is not applied from the bus bars 60 to the external connection terminals 23 through 25. This prevents the external connection terminals 23 through 25 from deforming. In addition, stress applied to the terminal blocks 12b through 12d which support the external connection terminals 23 through 25 respectively is suppressed and the sealing body portion 10 does not break. Accordingly, insulation is maintained. As a result, deterioration in the reliability of the semiconductor device 1 is suppressed.

That is to say, there is need for the protrusions 20a and 20b to be formed in positions which suppress rotation of the bus bar 60. Accordingly, the positions or the number of the protrusions 20a and 20b is not limited to the positions or the number illustrated in FIG. 4 and the shape of the protrusions 20a and 20b is not limited to a pillar. The bus bar 60 rotates clockwise on a bolt (nut 70). Therefore, there is need for protrusions to be formed on the front surface 11 adjacently to side portions of contact areas Sa through Sd of the long sides 60b and 60d and the short sides 60a and 60c of the bus bar 60 with which the protrusions come in contact at the time of rotating the bus bar 60 on the opening portion 63a in the clockwise direction (in the fastening direction). That is to say, for example, the contact area Sa extends from the center of the short side 60a of the bus bar 60 to a left end portion of the short side 60a which rotates in the clockwise direction. Similarly, the contact area Sb extends from the center of the long side 60b of the bus bar 60 to a left end portion of the long side 60b which rotates in the clockwise direction. The contact area Sc extends from the center of the short side 60c of the bus bar 60 to a left end portion of the short side 60c which rotates in the clockwise direction. The contact area Sd extends from the center of the long side 60d of the bus bar 60 to a left end portion of the long side 60d which rotates in the clockwise direction. Protrusions are preferably formed adjacently to outer side portions of the contact areas Sa through Sd, particularly with an angular moment taken into consideration. Accordingly, various shapes or formation positions of protrusions will now be described. In the following modifications a case where a bus bar 60 is fixed over a nut housing stand 14 is also taken as an example. The formation of protrusions is applied in the same way with nut housing stands 13 and 15.

### Modification 1-1

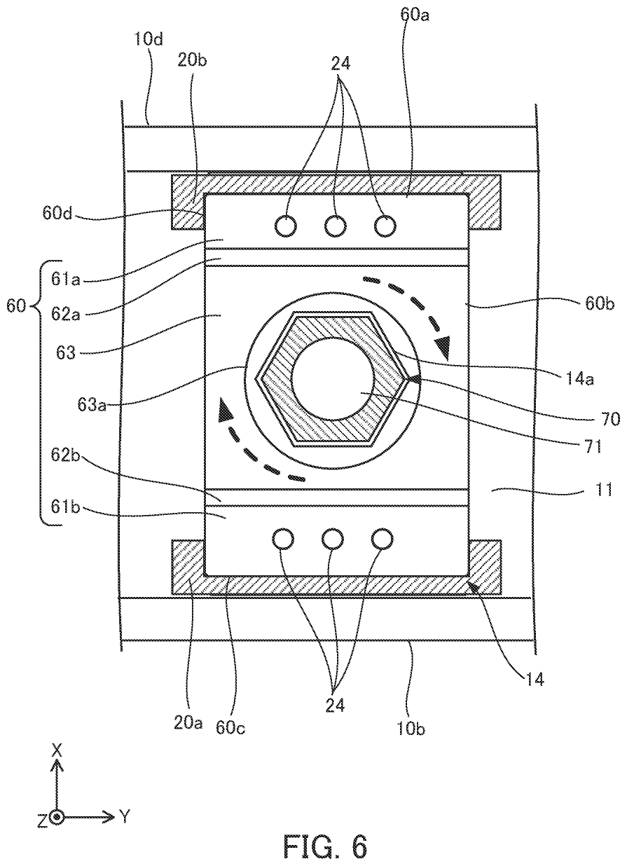

The semiconductor device 1 according to modification 1-1 will be described with reference to FIG. 6. FIG. 6 is a plan view illustrating a main part of the semiconductor device according to modification 1-1 of the first embodiment to which a bus bar is fixed. With the semiconductor device according to modification 1-1, a protrusion 20b has the shape of the letter “U” in a plan view, encloses a short side 60a of a bus bar 60, a portion on the short side 60a side of a long side 60b of the bus bar 60, and a portion on the short side 60a side of a long side 60d of the bus bar 60, and is formed on a front surface 11. Furthermore, a protrusion 20a has the shape of the letter “U” in the plan view, encloses a short side 60c of the bus bar 60, a portion on the short side 60c side of the long side 60b of the bus bar 60, and a portion on the short side 60c side of the long side 60d of the bus bar 60, and is formed on the front surface 11. That is to say, the protrusion 20b is formed adjacently to a side portion of a contact area Sa of the bus bar 60 and adjacently to a side portion of a portion of a contact area Sb of the bus bar 60. The protrusion 20a is formed adjacently to a side portion of a contact area Sc of the bus bar 60 and adjacently to a side portion of a portion of a contact area Sd of the bus bar 60. Furthermore, upper end portions of the protrusions 20b and 20a in modification 1-1 are situated over bonding areas 61a and 61b, respectively, of the bus bar 60 bonded to external connection terminals 24.

Even when a bolt is rotated clockwise with respect to a nut 70 in modification 1-1 to make an attempt to rotate the bus bar 60 clockwise, rotation of the bus bar 60 is suppressed by the protrusions 20b and 20a. Furthermore, in the case of modification 1-1, even if the bus bar 60 has a shock from the outside, for example, at the time of carrying or handling the semiconductor device 1, positional deviation is prevented. Accordingly, force is not applied from the bus bars 60 to the external connection terminals 24. This prevents the external connection terminals 24 from deforming. In addition, stress applied to a terminal block 12c which supports the external connection terminals 24 is suppressed and a sealing body portion 10 does not break. Accordingly, insulation is maintained. As a result, deterioration in the reliability of the semiconductor device 1 is suppressed.

Furthermore, the protrusions 20b and 20a make registration between the bus bar 60 and the external connection terminals 24 easy, compared with the case of FIG.

4. As a result, the bus bar 60 is easily bonded to the external connection terminals 24.

### Modification 1-2

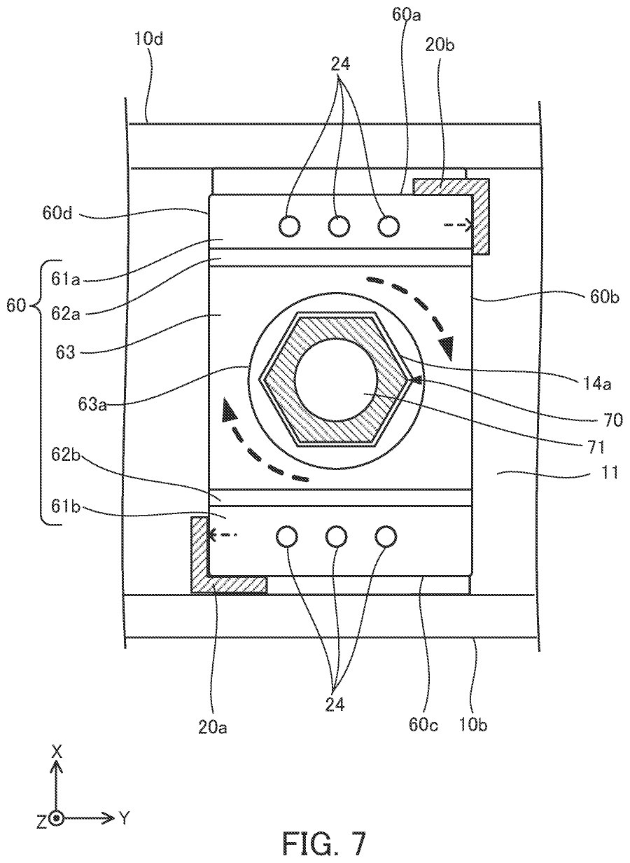

The semiconductor device 1 according to modification 1-2 will be described with reference to FIG. 7. FIG. 7 is a plan view illustrating a main part of the semiconductor device according to modification 1-2 of the first embodiment to which a bus bar is fixed. With the semiconductor device according to modification 1-2, a protrusion 20b has the shape of the letter “L” in a plan view and is formed on a front surface 11 so as to be in contact with a portion on the long side 60b side of a short side 60a of a bus bar 60 and a portion on the short side 60a side of the long side 60b of the bus bar 60. Furthermore, a protrusion 20a has the shape of the letter

“L” in the plan view and is formed on the front surface 11 so as to be in contact with a portion on the long side 60d side of a short side 60c of the bus bar 60 and a portion on the short side 60c side of the long side 60d of the bus bar 60. That is to say, the protrusion 20b is formed adjacently to a side portion of a contact area Sb of the bus bar 60. The protrusion 20a is formed adjacently to a side portion of a contact area Sd of the bus bar 60. In addition, upper end portions of the protrusions 20b and 20a in modification 1-2 are situated over bonding areas 61a and 61b, respectively, of the bus bar 60 bonded to external connection terminals 24.

Even when a bolt is rotated clockwise with respect to a nut 70 in modification 1-2 to make an attempt to rotate the bus bar 60 clockwise, rotation of the bus bar 60 is suppressed by the protrusions 20b and 20a. In particular, the protrusions 20b and 20a are in contact with the outside of the contact areas Sb and Sd respectively. Accordingly, the protrusions 20b and 20a reliably suppress rotation of the bus bar 60 compared with the case of FIG. 4. Furthermore, in the case of modification 1-2, even if the bus bar 60 has a shock from the outside, positional deviation is prevented. Accordingly, force is not applied from the bus bars 60 to the external connection terminals 24. This prevents the external connection terminals 24 from deforming. In addition, stress applied to a terminal block 12c which supports the external connection terminals 24 is suppressed and a sealing body portion 10 does not break. Accordingly, insulation is maintained. As a result, deterioration in the reliability of the semiconductor device 1 is suppressed.

Furthermore, the protrusions 20b and 20a make registration between the bus bar 60 and the external connection terminals 24 easy, compared with the case of FIG. 4. As a result, the bus bar 60 is easily bonded to the external connection terminals 24.

### Modification 1-3

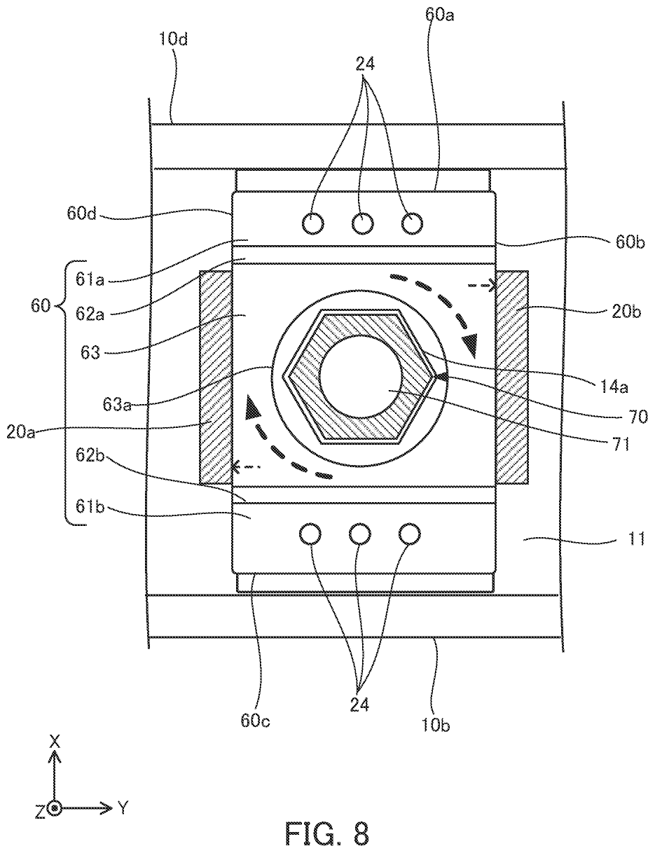

The semiconductor device 1 according to modification 1-3 will be described with reference to FIG. 8. FIG. 8 is a plan view illustrating a main part of the semiconductor device according to modification 1-3 of the first embodiment to which a bus bar is fixed. With the semiconductor device according to modification 1-3, a protrusion 20b has the shape of the letter “I” in a plan view and is formed on a front surface 11 so as to be in contact with portions on both sides of the center of a long side 60b of a bus bar 60. Furthermore, a protrusion 20a has the shape of the letter “I” in the plan view and is formed on the front surface 11 so as to be in contact with portions on both sides of the center of a long side 60d of the bus bar 60. That is to say, the protrusion 20b is formed adjacently to a side portion of a contact area Sb of the bus bar 60. The protrusion 20a is formed adjacently to a side portion of a contact area Sd of the bus bar 60. In addition, upper end portions of the protrusions 20b and 20a in modification 1-3 are situated over bonding areas 61a and 61b, respectively, of the bus bar 60 bonded to external connection terminals 24.

Even when a bolt is rotated clockwise with respect to a nut 70 in modification 1-3 to make an attempt to rotate the bus bar 60 clockwise, rotation of the bus bar 60 is suppressed by the protrusions 20b and 20a. Furthermore, in the case of modification 1-3, even if the bus bar 60 has a shock from the outside particularly in the Y direction, positional deviation is prevented. Accordingly, force is not applied from the bus bars 60 to the external connection terminals 24. This prevents the external connection terminals 24 from deforming. In addition, stress applied to a terminal block 12c which supports the external connection terminals 24 is suppressed and a sealing body portion 10 does not break. Accordingly, insulation is maintained. As a result, deterioration in the reliability of the semiconductor device 1 is suppressed.

Furthermore, when the bus bar 60 is fixed, the protrusions 20b and 20a are also used for registration. As a result, registration between the bus bar 60 and the external connection terminals 24 is easily performed and the bus bar 60 is easily bonded to the external connection terminals 24.

### Modification 1-4

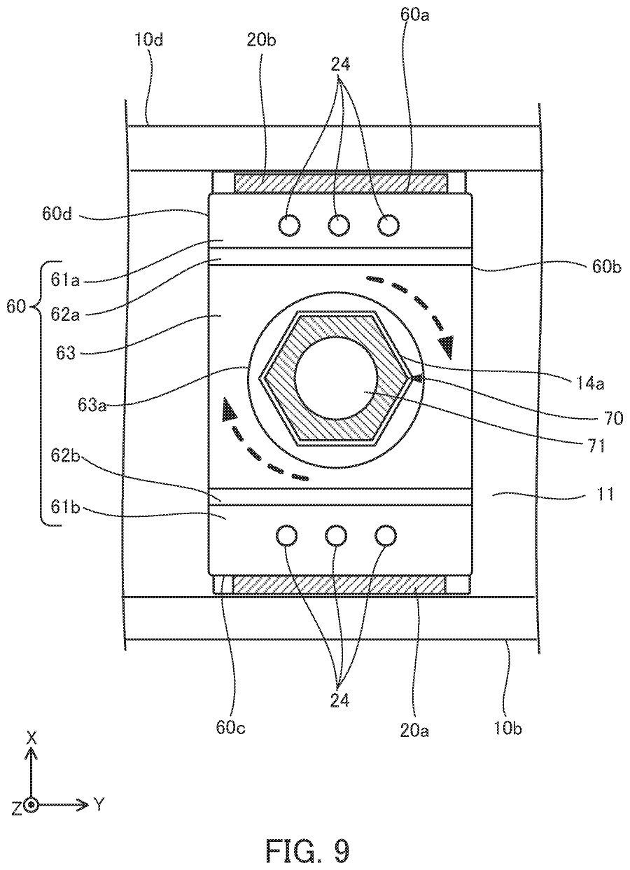

The semiconductor device 1 according to modification 1-4 will be described with reference to FIG. 9. FIG. 9 is a plan view illustrating a main part of the semiconductor device according to modification 1-4 of the first embodiment to which a bus bar is fixed. With the semiconductor device according to modification 1-4, a protrusion 20b has the shape of the letter “I” in a plan view and is formed on a front surface 11 so as to be in contact with portions on both sides of the center of a short side 60a of a bus bar 60. Furthermore, a protrusion 20a has the shape of the letter “I” in the plan view and is formed on the front surface 11 so as to be in contact with portions on both sides of the center of a short side 60c of the bus bar 60. That is to say, the protrusion 20b is formed adjacently to a side portion of a contact area Sa of the bus bar 60. The protrusion 20a is formed adjacently to a side portion of a contact area Sc of the bus bar 60. In addition, upper end portions of the protrusions 20b and 20a in modification 1-4 are situated over bonding areas 61a and 61b, respectively, of the bus bar 60 bonded to external connection terminals 24.

Even when a bolt is rotated clockwise with respect to a nut 70 in modification 1-4 to make an attempt to rotate the bus bar 60 clockwise, rotation of the bus bar 60 is suppressed by the protrusions 20b and 20a. Furthermore, in the case of modification 1-4, even if the bus bar 60 has a shock from the outside particularly in the X direction or is subject to influence from the outside particularly in the X direction, positional deviation is prevented. Accordingly, force is not applied from the bus bars 60 to the external connection terminals 24. This prevents the external connection terminals 24 from deforming. In addition, stress applied to a terminal block 12c which supports the external connection terminals 24 is suppressed and a sealing body portion 10 does not break. Accordingly, insulation is maintained. As a result, deterioration in the reliability of the semiconductor device 1 is suppressed.

Furthermore, when the bus bar 60 is fixed, the protrusions 20b and 20a are also used for registration. As a result, registration between the bus bar 60 and the external connection terminals 24 is easily performed and the bus bar 60 is easily bonded to the external connection terminals 24.

### Modification 1-5

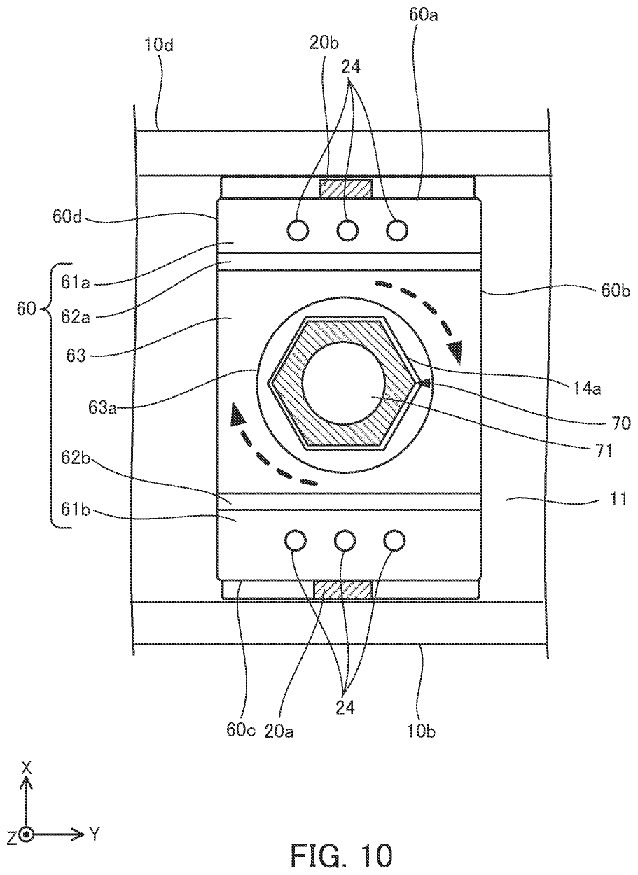

The semiconductor device 1 according to modification 1-5 will be described with reference to FIG. 10. FIG. 10 is a plan view illustrating a main part of the semiconductor device according to modification 1-5 of the first embodiment to which a bus bar is fixed. With the semiconductor device according to modification 1-5, a protrusion 20b has the shape of the letter “I” in a plan view and is formed on a front surface 11 so as to be in contact with a portion in the vicinity of the center of a short side 60a of a bus bar 60. Furthermore, a protrusion 20a has the shape of the letter “I” in the plan view and is formed on the front surface 11 so as to be in contact with a portion in the vicinity of the center of a short side 60c of the bus bar 60. That is to say, the protrusion 20b is formed adjacently to a side portion of a contact area Sa of the bus bar 60. The protrusion 20a is formed adjacently to a side portion of a contact area Sc of the bus bar 60. In addition, upper end portions of the protrusions 20b and 20a in modification 1-5 are situated over bonding areas 61a and 61b, respectively, of the bus bar 60 bonded to external connection terminals 24.

Even when a bolt is rotated clockwise with respect to a nut 70 in modification 1-5 to make an attempt to rotate the bus bar 60 clockwise, rotation of the bus bar 60 is suppressed by the protrusions 20b and 20a. Furthermore, in the case of modification 1-5, even if the bus bar 60 has a shock from the outside particularly in the X direction or is subject to influence from the outside particularly in the X direction, positional deviation is prevented. Accordingly, force is not applied from the bus bars 60 to the external connection terminals 24. This prevents the external connection terminals 24 from deforming. In addition, stress applied to a terminal block 12c which supports the external connection terminals 24 is suppressed and a sealing body portion 10 does not break. Accordingly, insulation is maintained. As a result, deterioration in the reliability of the semiconductor device 1 is suppressed.

Furthermore, when the bus bar 60 is fixed, the protrusions 20b and 20a are also used for registration. As a result, registration between the bus bar 60 and the external connection terminals 24 is easily performed and the bus bar 60 is easily bonded to the external connection terminals 24.

### Modification 1-6

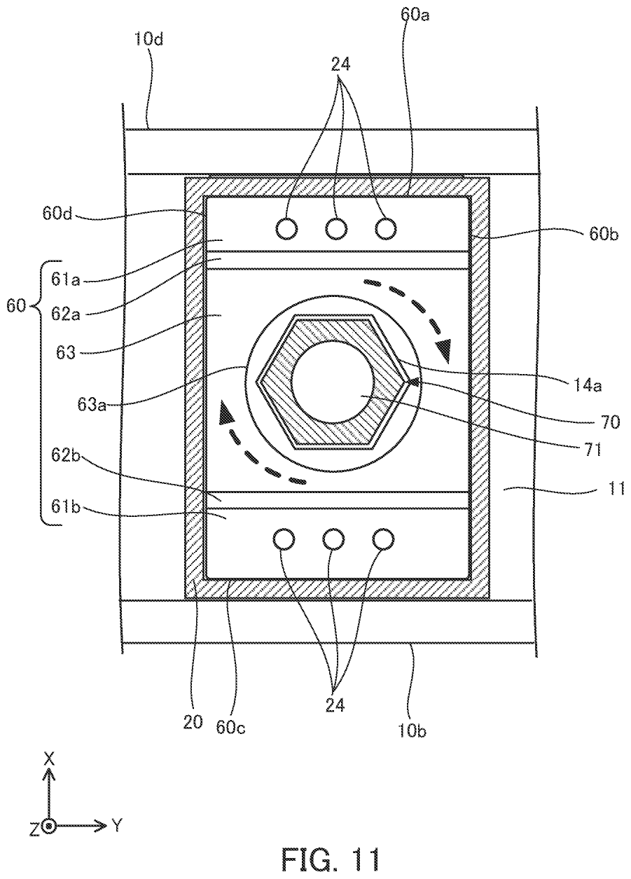

The semiconductor device 1 according to modification 1-6 will be described with reference to FIG. 11. FIG. 11 is a plan view illustrating a main part of the semiconductor device according to modification 1-6 of the first embodiment to which a bus bar is fixed. With the semiconductor device according to modification 1-6, a protrusion 20 is formed on a front surface 11 along short sides 60a and 60c and long sides 60b and 60d of a bus bar 60 in a plan view so as to be in contact with the short sides 60a and 60c and the long sides 60b and 60d. That is to say, the protrusion 20 is formed adjacently to side portions of contact areas Sa through Sd of the bus bar 60. In addition, an upper end portion of the protrusion 20 in modification 1-6 is situated over at least bonding areas 61a and 61b of the bus bar 60 bonded to external connection terminals 24.

Even when a bolt is rotated clockwise with respect to a nut 70 in modification 1-6 to make an attempt to rotate the bus bar 60 clockwise, rotation of the bus bar 60 is suppressed by the protrusion 20. Furthermore, in the case of modification 1-6, the protrusion 20 is formed along the whole perimeter of the bus bar 60. Accordingly, even if the bus bar 60 has a shock from the outside, positional deviation is prevented more reliably. As a result, force is not applied from the bus bars 60 to the external connection terminals 24. This prevents the external connection terminals 24 from deforming. In addition, stress applied to a terminal block 12c which supports the external connection terminals 24 is suppressed and a sealing body portion 10 does not break. Accordingly, insulation is maintained. As a result, deterioration in the reliability of the semiconductor device 1 is suppressed.

Furthermore, when the bus bar 60 is fixed, the protrusion 20 is also used for registration. As a result, registration between the bus bar 60 and the external connection terminals 24 is easily performed and the bus bar 60 is easily bonded to the external connection terminals 24.

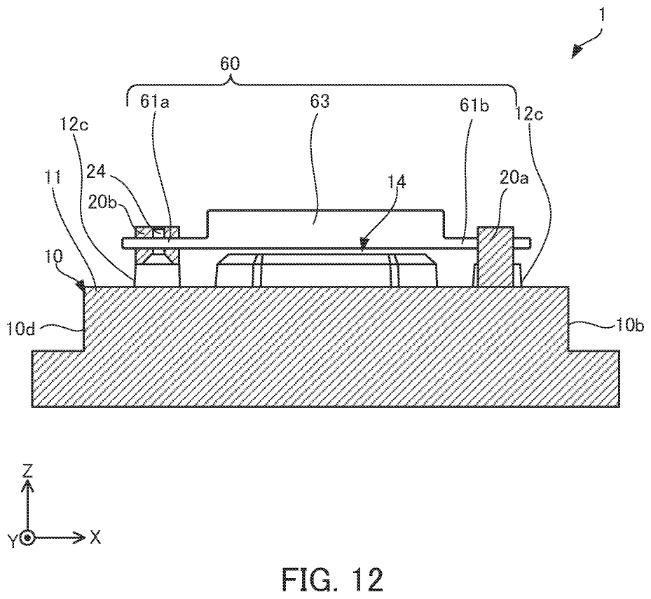

As illustrated in FIG. 5, the thickness of the bus bar 60 included in the semiconductor device 1 according to the first embodiment is constant across the bus bar 60. Furthermore, the front surface of the fastening area 63 protrudes upward from the front surfaces of the bonding areas 61a and 61b perpendicularly to the front surface 11 of the sealing body portion 10. However, the shape of the bus bar 60 is not limited to the case of FIG. 5. For example, the bus bar 60 may have a shape illustrated in FIG. 12. FIG. 12 is a sectional view of the semiconductor device according to the first embodiment to which another bus bar is fixed. The semiconductor device 1 illustrated in FIG. 12 is equal in structure to the semiconductor device 1 illustrated in FIG. 5 except the bus bar 60. The bus bar 60 illustrated in FIG. 12 includes bonding areas 61a and 61b and a fastening area 63. The back surface of the fastening area 63 is flush with the back surfaces of the bonding areas 61a and 61b and the bonding areas 61a and 61b are integrally connected to the fastening area 63. Furthermore, the fastening area 63 is thicker than the bonding areas 61a and 61b. As a result, the front surface of the fastening area 63 is situated above the front surfaces of the bonding areas 61a and 61b. An external connection terminal is fastened to even the bus bar 60 illustrated in FIG. 12 with a bolt. In addition, in even this case, the protrusions 20b and 20a illustrated in FIG. 4, the protrusions 20b and 20a according to modification 1-1, 1-2, 1-3, 1-4, or 1-5, or the protrusion 20 according to modification 1-6 may be formed and the same effect is obtained.

Furthermore, the protrusions 20b and 20a illustrated in FIG. 4, the protrusions 20b and 20a according to modifications 1-1, 1-2, 1-3, 1-4, and 1-5, and the protrusion 20 according to modification 1-6 may properly be combined and formed. For example, the protrusions 20b and 20a according to modification 1-2 (FIG. 7) and the protrusions 20b and 20a according to modification 1-5 (FIG. 10) may be formed.

### Second Embodiment

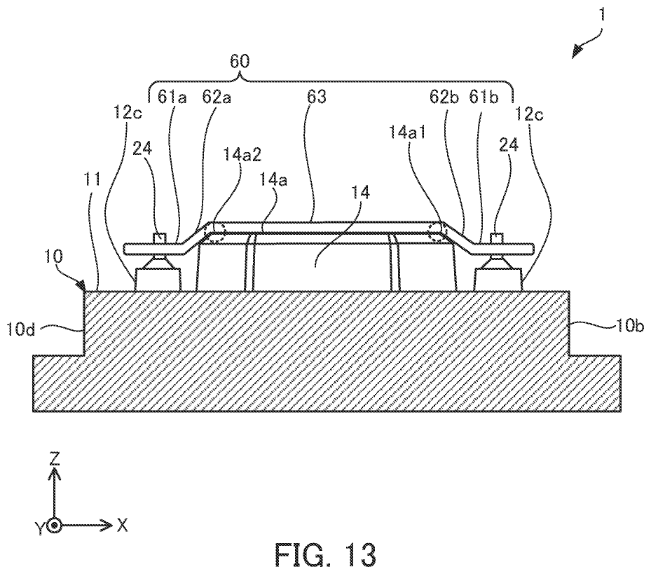

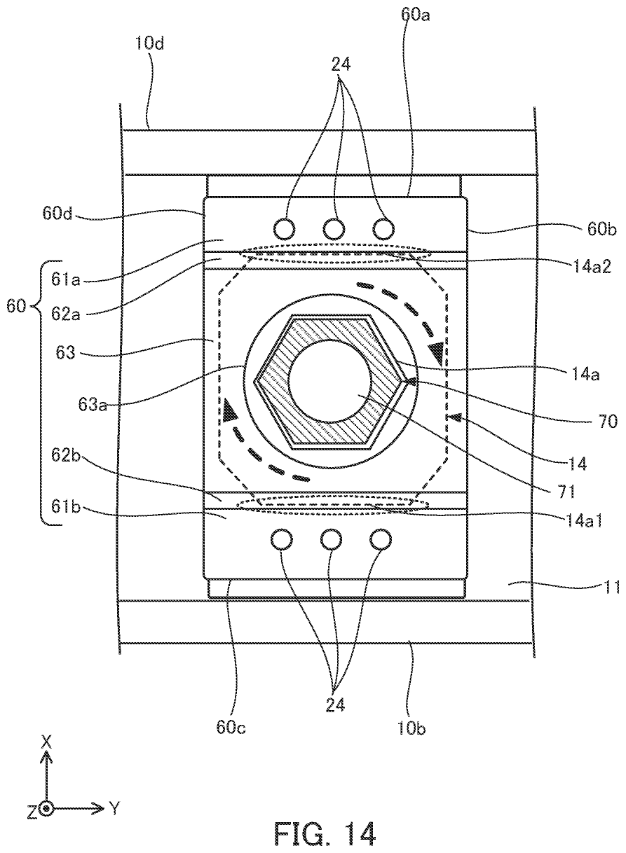

A semiconductor device according to a second embodiment will be described with reference to FIG. 13 and FIG. 14. FIG. 13 is a sectional view of a semiconductor device according to a second embodiment to which a bus bar is fixed. FIG. 14 is a plan view illustrating a main part of the semiconductor device according to the second embodiment to which the bus bar is fixed. FIGS. 13 and 14 which illustrate the semiconductor device 1 according to the second embodiment correspond to FIGS. 3 and 4, respectively, in the first embodiment. Furthermore, in FIG. 14, an opposite surface 14b of a nut housing stand 14 is indicated by a dashed line in a fastening area 63.

Unlike the semiconductor device 1 according to the first embodiment (FIG. 1 through FIG. 5), protrusions 20b and 20a are not formed in the second embodiment. In the second embodiment, nut housing stands 13 through 15 protrude upward (in the +Z direction) perpendicularly to a front surface 11 so as to be in contact with the back surfaces of bus bars 60. That is to say, as illustrated in FIG. 13 and FIG. 14, sides 14a1 and 14a2 of an opposite surface 14b of the nut housing stand 14 on the sides of side walls 10b and 10d are put between connection areas 62a and 62b on the back surface of the bus bar 60. That is to say, the sides 14a1 and 14a2 of the opposite surface 14b of the nut housing stand 14 are put between an area between a boundary between the fastening area 63 and the connection area 62a and a boundary between the connection area 62a and a bonding area 61a and an area between a boundary between the fastening area 63 and the connection area 62b and a boundary between the connection area 62b and a bonding area 61b.

Furthermore, as illustrated in FIG. 13, at this time it is desirable that the sides 14a1 and 14a2 of the opposite surface 14b of the nut housing stand 14 be in contact with a boundary area between the fastening area 63 and the connection area 62b and a boundary area between the fastening area 63 and the connection area 62a and that the sides 14a1 and 14a2 of the opposite surface 14b of the nut housing stand 14 be put between these boundary areas. In this case, the opposite surface 14b of the nut housing stand 14 is reliably put between the connection areas 62a and 62b. As a result, positional deviation between an opening portion 63a of the bus bar 60 and a housing portion 14a is prevented.

There is not always need for the sides 14a1 and 14a2 of the opposite surface 14b of the nut housing stand 14 to be in contact with the connection areas 62b and 62a, respectively, of the bus bar 60. As described later, as long as rotation of the bus bar 60 is nearly suppressed, there may be small gaps between the sides 14a1 and 14a2 of the opposite surface 14b of the nut housing stand 14 and the connection areas 62b and 62a, respectively, of the bus bar 60.

As described in the first embodiment, a connection terminal is fixed from the outside to the bus bar 60, a bolt is made to pierce the connection terminal and the opening portion 63a of the bus bar 60, the bolt is rotated clockwise, and the bolt is fastened to a nut in the housing portion 14a. Even if the bolt is rotated clockwise at this time to make an attempt to rotate the bus bar 60 clockwise, rotation of the bus bar 60 is suppressed because the sides 14a1 and 14a2 of the opposite surface 14b of the nut housing stand 14 are in contact with the connection areas 62b and 62a, respectively, of the bus bar 60. As a result, force is not applied from the bus bar 60 to external connection terminals 24. This prevents the external connection terminals 24 from deforming. In addition, stress applied to a terminal block 12c which supports the external connection terminals 24 is suppressed and a sealing body portion 10 does not break. Accordingly, insulation is maintained.

With the semiconductor device 1 according to the second embodiment, the protrusions 20a and 20b according to the first embodiment or modification 1-1, 1-2, 1-3, 1-4, or 1-5 or the protrusion 20 according to modification 1-6 may be formed as needed. By doing so, rotation of the bus bar 60 is suppressed more reliably.

According to the disclosed techniques, damage is prevented at the time of fastening a connection terminal form the outside and deterioration in the reliability of a semiconductor device is suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a sealing body portion having a housing portion formed on a front surface thereof, the sealing body portion including a semiconductor chip contained therein and a plurality of pin-shaped external connection terminals electrically connected to the semiconductor chip;
a nut having a screw hole and disposed in the housing portion; and
a bus bar arranged opposite the housing portion, and including
a fastening area with an opening portion opposite the screw hole of the nut, and
a bonding area that is outside the fastening area and is connected to the plurality of external connection terminals,
wherein the sealing body portion has a protrusion adjacent to the bonding area of the bus bar.

2. The semiconductor device according to claim 1, wherein the bus bar has an upper surface that includes
a first upper surface corresponding to the fastening area,
a second upper surface corresponding to the bonding area,
the first upper surface being farther from the front surface of the sealing body portion than the second upper surface.

3. The semiconductor device according to claim 2, wherein the bus bar further includes a connection area which connects the fastening area and the bonding area.

4. The semiconductor device according to claim 1, wherein
the bus bar has a contact area with which the protrusion comes in contact at a rotation of the bus bar, and
the protrusion is formed on a side of the contact area to restrict the rotation of the bus bar.

5. The semiconductor device according to claim 4, wherein the protrusion is provided in plurality.

6. The semiconductor device according to claim 4, wherein the protrusion is formed outside an outer peripheral portion of the bus bar including the contact area.

7. The semiconductor device according to claim 1, wherein the housing portion is formed to protrude out from the front surface of the sealing body portion toward a back surface of the fastening area.

8. The semiconductor device according to claim 1, wherein the housing portion is recessed in the front surface of the sealing body portion.

9. A semiconductor device, comprising:
a sealing body portion having a housing portion formed in a front surface thereof, the sealing body portion including a semiconductor chip contained therein and a plurality of pin-shaped external connection terminals electrically connected to the semiconductor chip;
a nut having a screw hole and housed in the housing portion; and
a plate-shaped bus bar arranged opposite the housing portion, and including
a fastening area with an opening portion opposite the screw hole of the nut, and
a plurality of bonding areas that are outside the fastening area and are connected to the plurality of external connection terminals, the fastening area protruding outward from the bonding areas with respect to the front surface of the sealing body portion, wherein
the housing portion protrudes outward from the front surface of the sealing body portion and is fitted into the fastening area.
